(19) United States
(12) Patent Application Publication
(10) Pub. No.: US 2014/0287155 A1
(43) Pub. Date: Sep. 25, 2014

(54) PRETREATMENT METHOD, GRAPHENE FORMING METHOD AND GRAPHENE FABRICATION APPARATUS

(71) Applicant: TOKYO ELECTRON LIMITED, Tokyo (JP)

(72) Inventor: Takashi Matsumoto, Tsukuba-shi (JP)

(73) Assignee: TOKYO ELECTRON LIMITED

(21) Appl. No.: 14/355,601

(22) PCT Filed: Nov. 5, 2012
(86) PCT No.: PCT/JP2012/078585

§ 371 Date: May 1, 2014

(30) Foreign Application Priority Data
Nov. 9, 2011 (JP) 2011-245747

(51) Int. Cl. C23C 16/26; C23C 16/511; C01B 31/04; C23C 16/02

(52) U.S. Cl. CPC C23C 16/26; C23C 16/02; C23C 16/511; C01B 31/0453
USPC 427/535; 427/444; 118/723 AN

(57) ABSTRACT

A pretreatment method is performed before a graphene grows by performing a CVD method on a catalyst metal layer formed on a workpiece. The method includes a plasma treatment process in which the catalyst metal layer is activated by applying plasma of a treatment gas including a reducing gas and a nitrogen-containing gas on the catalyst metal layer.

### TECHNICAL FIELD

The present invention relates to a pretreatment method for forming a graphene, a graphene forming method and a graphene fabrication apparatus.

### BACKGROUND

A graphene whose electron mobility is as high as 200,000 cm²/Vs is considered as a channel material for high speed operations. Moreover, the graphene is capable of implementing ballistic conduction which allows electrons to propagate with no scattering and is superior in electric conductivity (low in electric resistance). For example, Patent Document 1 (Japanese Patent Laid-open Publication No. 2011-96980) proposes using the graphene as a low-resistance semiconductor wiring material. In addition, the graphene has a property of propagating a spin with no scattering and is studied as a channel material for a spintronics device. Thus, the graphene draws attention as a core material for the next generation electronics.

As one example of a graphene growth method, Non-patent Document 1 [Jaeho Kim, APPLIED PHYSICS LETTERS 98, 091502 (2011)] discloses a method in which a copper foil of 30 μm in thickness and an aluminum foil of 12 μm in thickness are respectively cleaned with plasma of an Ar gas and a H₂ gas and is then subjected to CVD (Chemical Vapor Deposition) at a temperature of 300 to less than 400 degrees C. by generating surface wave plasma of a CH₄ gas, an Ar gas and a H₂ gas. Furthermore, Non-patent Document 2 [Alexander Malesevic, Nanotechnology 19 (2008) 305604] reports a graphene growth method in which a substrate made of quartz, silicon, platinum or the like is cleaned with plasma of a H₂ gas and is then subjected to CVD at a temperature of 700 degrees C. by generating microwave plasma of a CH₄ gas and a H₂ gas. Moreover, Non-patent Document 3 [Daiyu Kondo, Applied Physics Express 3 (2010) 025102] reports a graphene growth method in which an iron layer on a SiO₂/Si substrate is used as a catalyst and thermal CVD is performed at a temperature of 650 degrees C. using a C₂H₄ gas and an Ar gas as source gases. In addition, Patent Document 2 (Japanese Patent Laid-open Publication No. 2011-102231) proposes a method in which a Ni-containing catalyst layer containing Ni and Cu is formed as a catalyst for the growth of a graphene by a CVD method.

However, if the graphene grows by performing a CVD method at a low temperature less than 500 degrees C. as disclosed in Non-patent document 1, the crystallinity of the graphene is reduced to about 1/10 as compared with a case where a graphene grows by performing a CVD method at a high temperature of about 650 to 1000 degrees C. For that reason, in order to obtain a high-quality graphene using a CVD method, it is effective to increase the growth temperature to increase the crystallinity. However, the deposition performed at a high temperature poses a problem in that the materials of a substrate or a material film are restricted and the thermal hysteresis is increased.

### SUMMARY

The present invention provides a method of efficiently growing a high-crystallinity and high-quality graphene at a very low temperature.

A pretreatment method of the present invention is a pretreatment method performed before a graphene grow by performing a CVD method on a catalyst metal layer formed on a workpiece. The pretreatment method includes a plasma treatment process in which the catalyst metal layer is activated by applying plasma of a treatment gas including a reducing gas and a nitrogen-containing gas on the catalyst metal layer.

In the pretreatment method of the present invention, the volume ratio of the reducing gas to the nitrogen-containing gas is preferably within a range of from 10:1 to 1:10.

In the pretreatment method of the present invention, the reducing gas may be a hydrogen gas, and the nitrogen-containing gas may be a nitrogen gas or an ammonia gas. The reducing gas may be a hydrogen gas or an ammonia gas, and the nitrogen-containing gas may be a nitrogen gas.

In the pretreatment method of the present invention, the catalyst metal layer may be made of one or more kinds of metals selected from the group consisting of Ni, Co, Cu, Ru, Pd and Pt.

A graphene forming method of the present invention includes a plasma treatment process in which a surface of a catalyst metal layer is activated by the pretreatment method recited above, and a process to grow a graphene by a CVD method on the catalyst metal layer subjected to the plasma treatment.

In the graphene forming method of the present invention, the process to grow the graphene may be performed by a plasma CVD method. In this case, the temperature of the treatment performed by the plasma CVD method is preferably within a range of from 300 degrees C. to 600 degrees C. Furthermore, it is preferred that, in the plasma CVD method, source gas plasma is generated by introducing microwaves into a processing vessel through a planar antenna having a plurality of microwave radiating holes, and the graphene is formed by the source gas plasma. It is more preferred that the planar antenna is a radial line slot antenna.

In the graphene forming method of the present invention, the process to grow the graphene is performed by a thermal CVD method. In this case, it is preferred that a treatment temperature of the thermal CVD method is within a range of from 300 degrees C. to 600 degrees C.

A graphene fabrication apparatus of the present invention includes a processing vessel configured to process a workpiece and provided with an upper opening portion, a mounting stand arranged within the processing vessel and configured to mount the workpiece thereon, a dielectric plate configured to close the opening portion of the processing vessel, a planar antenna installed outside the dielectric plate and configured to introduce microwaves into the processing vessel, the planar antenna including a plurality of microwave radiating holes, a gas introduction unit configured to introduce a treatment gas into the processing vessel, the gas introduction unit including a plurality of gas discharge holes formed to face the workpiece mounted on the mounting stand, and an exhaust port connected to an exhaust device which depressurizes and evacuates the interior of the processing vessel. In the graphene fabrication apparatus of the present invention, the gas introduction unit is connected to a gas supply source configured to supply a treatment gas including a reducing gas and a nitrogen-containing gas used in a pretreatment performed prior to a growth of a graphene on a catalyst metal layer formed on the workpiece and a source gas supply source configured to supply a source gas of the graphene used in a process to grow the graphene by a CVD method on the catalyst metal layer subjected to the pretreatment.

The graphene fabrication apparatus of the present invention may be configured such that the pretreatment and the process to grow the graphene are performed one after another within the same processing vessel.

In the graphene fabrication apparatus of the present invention, the gas introduction unit may include a plurality of gas discharge holes formed to face a surface of the workpiece mounted on the mounting stand.

### BRIEF DESCRIPTION OF THE DRAWINGS

FIG. 1 is a sectional view schematically illustrating a configuration example of a processing apparatus that can be used in a pretreatment method and a graphene forming method according to one embodiment of the present invention.

FIG. 2 is a view illustrating a configuration example of a planar antenna employed in the processing apparatus shown in FIG. 1.

FIG. 3 is a bottom view illustrating a configuration example of a shower plate employed in the processing apparatus shown in FIG. 1.

FIG. 4 is a view explaining a configuration example of a control unit employed in the processing apparatus shown in FIG. 1.

FIG. 5A is a schematic diagram illustrating a structure of a wafer having a catalyst metal layer as a processing target.

FIG. 5B is a schematic diagram explaining the catalyst metal layer activated by an activating treatment.

FIG. 5C is a view schematically explaining a state in which graphenes are formed.

FIG. 6A is a scanning electron microscope (SEM) image of a substrate cross section showing the result of a graphene forming test (a Ni catalyst metal layer) of example 1.

FIG. 6B is a scanning electron microscope (SEM) image of a substrate cross section showing the result of a graphene forming test (a Co catalyst metal layer) of example 1.

FIG. 6C is a transmission electron microscope (TEM) image of a substrate cross section showing the result of a graphene forming test (a Ni catalyst metal layer) of example 1.

FIG. 6D is an enlarged image of a major portion of FIG. 6C.

FIG. 7A is a scanning electron microscope (SEM) image of a substrate cross section showing the result of a graphene forming test (a Ni catalyst metal layer) of example 2.

FIG. 7B is a scanning electron microscope (SEM) image of a substrate cross section showing the result of a graphene forming test (a Co catalyst metal layer) of example 2.

FIG. 8A is a scanning electron microscope (SEM) image of a substrate cross section showing the result of a graphene forming test (a Ni catalyst metal layer) of example 3.

FIG. 8B is a scanning electron microscope (SEM) image of a substrate cross section showing the result of a graphene forming test (a Co catalyst metal layer) of example 3.

FIG. 9A is a transmission electron microscope (TEM) image of a substrate cross section showing the result of a graphene forming test (the graphene growth time: 1 minute) of example 4.

FIG. 9B is a transmission electron microscope (TEM) image of a substrate cross section showing the result of a graphene forming test (the graphene growth time: 3 minutes) of example 4.

FIG. 9C is a transmission electron microscope (TEM) image of a substrate cross section showing the result of a graphene forming test (the graphene growth time: 5 minutes) of example 4.

FIG. 9D is a transmission electron microscope (TEM) image of a substrate cross section showing the result of a graphene forming test (the graphene growth time: 15 minutes) of example 4.

FIG. 10 is a chart illustrating the result of measurement of the graphenes obtained in example 4, which are measured by a Raman scattering spectroscopy.

FIG. 11A is a transmission electron microscope (TEM) image of a substrate cross section showing the result of a graphene forming test (the processing temperature: 350 degrees C.) of example 5.

FIG. 11B is a transmission electron microscope (TEM) image of a substrate cross section showing the result of a graphene forming test (the processing temperature: 390 degrees C.) of example 5.

FIG. 12 is a transmission electron microscope (TEM) image of a substrate cross section showing the result of a graphene forming test of example 6.

FIG. 13 is a transmission electron microscope (TEM) image of a substrate cross section showing the result of a graphene forming test of example 7.

FIG. 14A is a scanning electron microscope (SEM) image of a substrate cross section showing the result of a graphene forming test (a Ni catalyst metal layer) of example 8.

FIG. 14B is a scanning electron microscope (SEM) image of a substrate cross section showing the result of a graphene forming test (a Co catalyst metal layer) of example 8.

FIG. 15A is a scanning electron microscope (SEM) image of a substrate cross section showing the result of a graphene forming test (a Ni catalyst metal layer) of example 9.

FIG. 15B is a scanning electron microscope (SEM) image of a substrate cross section showing the result of a graphene forming test (a Co catalyst metal layer) of example 9.

### DETAILED DESCRIPTION

An embodiment of the present invention will now be described in detail with reference to the accompanying drawings.

### <Processing Apparatus>

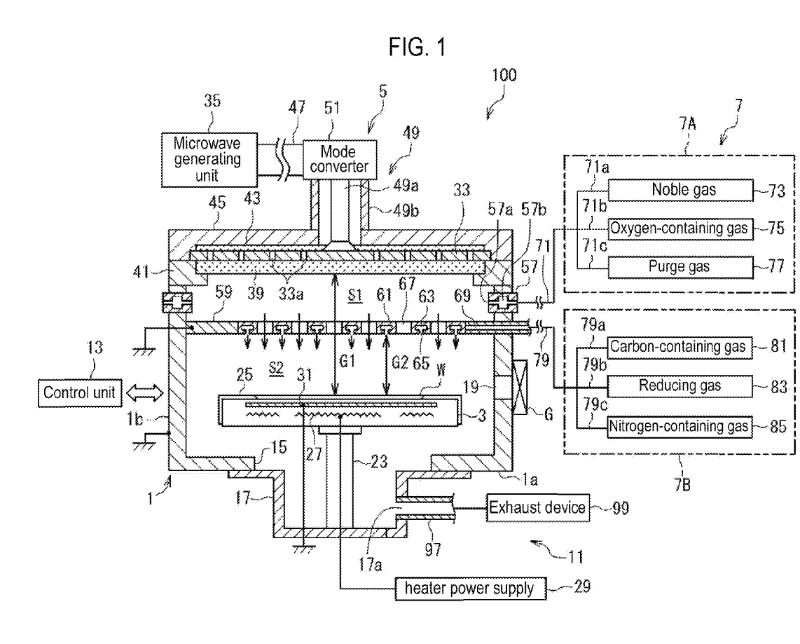

First, the description will be made on the outline of a processing apparatus that can be used in a pretreatment method and a graphene forming method according to one embodiment of the present invention. FIG. 1 is a sectional view schematically illustrating one example of the processing apparatus. The processing apparatus 100 shown in FIG. 1 is configured by a RLSA (Radial Line Slot Antenna)-type microwave plasma treatment apparatus that can form homogeneous microwave plasma within a processing vessel 1 by irradiating microwaves from a plurality of microwave radiating holes of a planar antenna. The microwave plasma is low-electron-temperature plasma mainly composed of radicals and is, therefore, suitable for an activating treatment of a catalyst metal layer as a pretreatment for forming a graphene. The processing apparatus 100 can be uses as a thermal CVD apparatus that forms the graphene by a thermal CVD method, or a plasma CVD apparatus that forms a graphene by a plasma CVD method.

The processing apparatus 100 includes, as its major components, a substantially cylindrical processing vessel 1, a stage 3 installed within the processing vessel 1 and configured to mount a semiconductor wafer (hereinafter just referred to as a “wafer”) W as a workpiece (workpiece substrate), a microwave introduction unit 5 configured to introduce microwaves into the processing vessel 1, a gas supply unit 7 configured to guide a gas into the processing vessel 1, an exhaust unit 11 configured to evacuate the interior of the processing vessel 1, and a control unit 13 configured to control the respective constituent parts of the processing apparatus 100.

### <Processing Vessel>

The processing vessel 1 is a grounded substantially-cylindrical vessel which is hermetically sealed so that it can be vacuum-drawn. The processing vessel 1 includes a bottom wall 1a and a sidewall 1b. The processing vessel 1 is a ground potential and is made of, e.g., a metallic material such as aluminum, aluminum alloy or stainless steel. A circular opening portion 15 is formed in the substantially central region of the bottom wall 1a of the processing vessel 1. An exhaust room 17 communicating with the opening portion 15 and protruding downward is installed in the bottom wall 1a. The exhaust room 17 may be a portion of the processing vessel 1. A carry-in/carry-out gate 19 for carrying in and carrying out the wafer W and a gate valve G for opening and closing the carry-in/carry-out gate 19 are installed in the sidewall 1b of the processing vessel 1.

### <Stage>

The stage 3 is made of, e.g., ceramic such as MN or the like. The stage 3 is supported by a ceramic-made cylindrical support member 23 extending upward from the bottom center of the exhaust room 17. A guide ring 25 for guiding the wafer W is installed in the outer edge portion of the stage 3. Lift pins (not shown) which are configured to move the wafer W up and down are installed within the stage 3 so that the lift pins can protrude and retract with respect to the upper surface of the stage 3.

A resistance heating type heater 27 is embedded within the stage 3. By supplying an electric current from a heater power supply 29 to the heater 27, it is possible for the heater 27 to heat the wafer W through the stage 3. A thermocouple (not shown) is inserted into the stage 3 so that the heating temperature of the wafer W can be controlled within a range of from 50 degrees C. to 650 degrees C. Unless specifically mentioned otherwise, the temperature of the wafer W does not mean the setting temperature of the heater 27 but means the temperature measured by the thermocouple. At the upper side of the heater 27, an electrode 31 having substantially the same size as the wafer W is embedded within the stage 3. The electrode 31 is grounded.

### <Microwave Introduction Unit>

The microwave introduction unit 5, which is installed above the processing vessel 1, includes a planar antenna 33 having a plurality of microwave radiating holes 33a, a microwave generating unit 35 configured to generate microwaves, a transmission plate 39 made of a dielectric material, a frame-shaped member 41 installed on the upper portion of the processing vessel 1, a slow-wave plate 43 made of a dielectric material and configured to adjust the wavelength of microwaves, and a cover member 45 configured to cover the planar antenna 33 and the slow-wave plate 43. The microwave introduction unit 5 further includes a waveguide tube 47 and a coaxial waveguide tube 49, both of which are configured to guide the microwaves generated in the microwave generating unit 35 to the planar antenna 33, and a mode converter 51 installed between the waveguide tube 47 and the coaxial waveguide tube 49.

The transmission plate 39 that transmits microwaves is made of a dielectric material, e.g., quartz or ceramic such as Al₂O₃, MN or the like. The transmission plate 39 is supported by the frame-shaped member 41. The clearance between the transmission plate 39 and the frame-shaped member 41 is hermetically sealed by a seal member (not shown) such as an O-ring or the like. Thus, the interior of the processing vessel 1 is kept gas-tight.

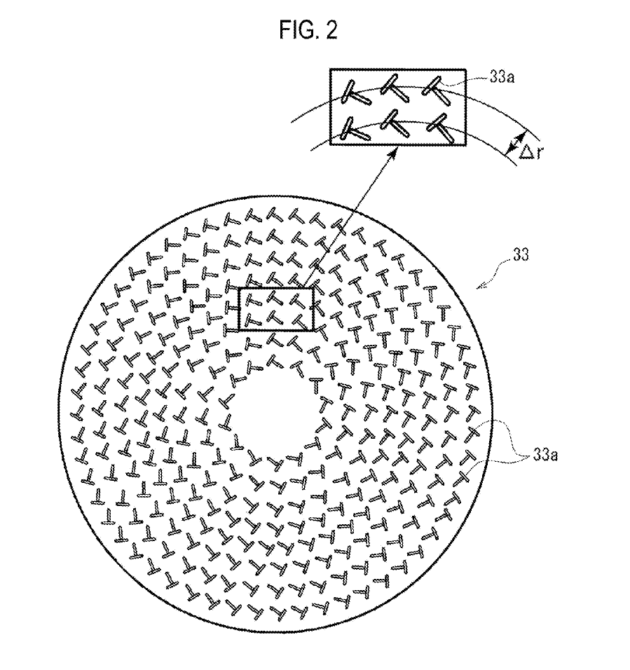

The planar antenna 33 is formed into, e.g., a disc shape, and is configured by an electrically conductive member such as a copper plate, an aluminum plate, a nickel plate or an alloy plate thereof whose surface is plated with gold or silver. The planar antenna 33 is arranged above the transmission plate 39 (outside the processing vessel 1) and is installed substantially parallel to the upper surface of the stage 3 (the surface on which the wafer W is mounted). The planar antenna 33 is supported by the frame-shaped member 41. The planar antenna 33 has a plurality of rectangular (slot-shaped) microwave radiating holes 33a through which microwaves are irradiated. The microwave radiating holes 33a are formed in a specified pattern through the thickness of the planar antenna 33. Typically, as illustrated in FIG. 2, the microwave radiating holes 33a adjoining each other are combined into a pair having a specified shape (e.g., a T-like shape). The pairs of the microwave radiating holes 33a as a whole are disposed in, e.g., a concentric pattern. The length and the arrangement interval of the microwave radiating holes 33a are decided depending on the wavelength (λg) of microwaves guided through the coaxial waveguide tube 49. For example, the microwave radiating holes 33a are disposed at an interval of λg/4 to λg. In FIG. 2, the spacing between the microwave radiating holes 33a concentrically formed in an adjoining relationship is indicated by Δr. The microwave radiating holes 33a may have other shapes such as a circular shape, an arc shape and so forth. The arrangement pattern of the microwave radiating holes 33a is not particularly limited. The microwave radiating holes 33a may be disposed in a pattern other than the concentric pattern, e.g., in a spiral pattern or a radial pattern.

The slow-wave plate 43 having a dielectric constant larger than a vacuum is installed on the upper surface of the planar antenna 33. Since the wavelength of microwaves becomes longer under a vacuum, the slow-wave plate 43 serves to shorten the wavelength of microwaves, thereby controlling the plasma. As a material of the slow-wave plate 43, it may be possible to use, e.g., quartz, polytetrafluoroethylene resin, polyimide resin or the like.

The cover member 45 is installed so as to cover the planar antenna 33 and the slow-wave member 43. The cover member 45 is made of, e.g., a metallic material such as aluminum or stainless steel. The coaxial waveguide tube 49 is connected to the center of the cover member 45. The coaxial waveguide tube 49 includes an inner conductor 49a extending upward from the center of the planar antenna 33 and an outer conductor 49b installed around the inner conductor 49a. The mode converter 51 is installed at the other end of the coaxial waveguide tube 49. The mode converter 51 and the microwave generating unit 35 are connected to the waveguide tube 47. The waveguide tube 47 is a rectangular waveguide tube extending in the horizontal direction. The mode converter 51 serves to convert the microwaves propagating in a TE mode through the waveguide tube 47 to a TEM mode. By virtue of the microwave introduction unit 5 configured as above, the microwaves generated in the microwave generating unit 35 are transmitted to the planar antenna 33 through the coaxial waveguide tube 49 and then introduced into the processing vessel 1 through the transmission plate 39. The frequency of microwaves is preferably, e.g., 2.45 GHz, and may be 8.35 GHz or 1.98 GHz. Unless specifically mentioned otherwise in the following description, it is to be understood that the microwaves having a frequency of 2.45 GHz are used.

### <Gas Supply Unit>

The gas supply unit 7 includes a first gas supply unit 7A and a second gas supply unit 7B. The first gas supply unit 7A includes a noble gas supply source 73, an oxygen-containing gas supply source 75 and a purge gas supply source 77. The second gas supply unit 7B includes a carbon-containing gas supply source 81, a reducing gas supply source 83 and a nitrogen-containing gas supply source 85. The first gas supply unit 7A is connected to a shower ring 57 as a first gas introduction member annularly extending along the inner wall of the processing vessel 1. The second gas supply unit 7B is connected to a shower plate 59 as a second gas introduction member disposed below the shower ring 57 and installed so as to divide the internal space of the processing vessel 1 into upper and lower spaces.

The shower ring 57 is disposed in the sidewall 1b of the processing vessel 1 and is installed in a height position between the transmission plate 39 and the shower plate 59. The shower ring 57 includes gas discharge holes 57a through which a gas is introduced into the internal space of the processing vessel 1 and a gas flow path 57b communicating with the gas discharge holes 57a. The gas flow path 57b is connected to the first gas supply unit 7A through a gas supply pipe 71. The first gas supply unit 7A includes three branch pipes 71a, 71b and 71c branched off from the gas supply pipe 71. Flow rate controllers and valves (not shown) are installed in the branch pipes 71a, 71b and 71c.

The branch pipe 71a is connected to the noble gas supply source 73 which supplies a noble gas used for the purpose of plasma generation. As the noble gas, it may be possible to use, e.g., Ar, He, Ne, Kr, Xe or the like. Among them, it is particularly preferable to use Ar which can stably generate plasma.

The branch pipe 71b is connected to the oxygen-containing gas supply source 75 which supplies an oxygen-containing gas used in cleaning the interior of the processing vessel 1. As the oxygen-containing gas, it may be possible to use, e.g., O₂, H₂O, O₃, N₂O or the like.

The branch pipe 71c is connected to the purge gas supply source 77 which supplies a purge gas. As the purge gas, the N₂ gas or the like may be used.

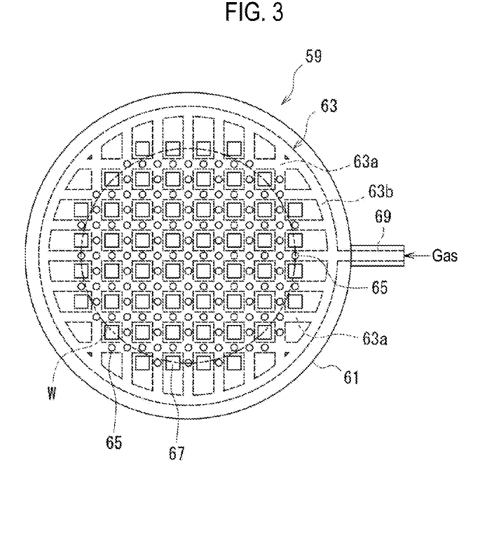

The shower plate 59, as a “gas introduction unit” for introducing a treatment gas for a pretreatment and a CVD process, is horizontally installed between the stage 3 existing within the processing vessel 1 and the microwave introduction unit 5. The shower plate 59 includes a gas distribution member 61 made of, e.g., aluminum, and formed into a lattice shape when seen in a plan view. The gas distribution member 61 includes gas flow paths 63 formed within a lattice-shaped body portion thereof and a plurality of gas discharge holes 65 formed in communication with the gas flow path 63 and opened toward the stage 3. A plurality of through-holes 67 is formed between the lattice-shaped gas flow paths 63. As shown in FIG. 3, the gas flow paths 63 include lattice-shaped flow paths 63a and a ring-shaped flow path 63b formed to be connected to and to surround the lattice-shaped flow paths 63a so that a gas may flow therethrough. A gas supply path 69 leading to the wall of the processing vessel 1 is connected to the gas flow paths 63 of the shower plate 59. The gas supply path 69 is connected to the second gas supply unit 7B through a gas supply pipe 79. The second gas supply unit 7B includes three branch pipes 79a, 79b and 79c branched off from the gas supply pipe 79. Flow rate controllers and valves (not shown) are installed in the branch pipes 79a, 79b and 79c.

The branch pipe 79a is connected to the carbon-containing gas supply source 81 which supplies a carbon-containing gas used as a graphene source. As the carbon-containing gas, it may be possible to use, e.g., ethylene (C₂H₄), methane (CH₄), ethane (C₂H₆), propane (C₃H₈), propylene (C₃H₆), acetylene (C₂H₂), methanol (CH₃OH), ethanol (C₂H₅OH) or the like.

The branch pipes 79b and 79c are connected to the gas supply sources which supply a treatment gas used in an activating treatment of a catalyst metal layer. As the treatment gas used in the activating treatment, a combination of a reducing gas and a nitrogen-containing gas may be used. In FIG. 1, the branch pipe 79b is connected to the reducing gas supply source 83 which supplies a reducing gas and the branch pipe 79c is connected to the nitrogen-containing gas supply source 85 which supplies a nitrogen-containing gas. As the reducing gas, a H₂ gas, a NH₃ gas or the like may be used. As the nitrogen-containing gas, a N₂ gas, a NH₃ gas or the like may be used. In this regard, the NH₃ gas has reducibility and contains nitrogen. For that reason, the NH₃ gas is classified as both the reducing gas and the nitrogen-containing gas. However, the NH₃ gas does not include a combination of the NH₃ gases (namely, the NH₃ gas alone). Accordingly, it may be possible to use a combination in which the reducing gas is a H₂ gas and the nitrogen-containing gas is a N₂ gas or a NH₃ gas. It may also be possible to use a combination in which the reducing gas is a H₂ gas or a NH₃ gas and the nitrogen-containing gas is a N₂ gas.

In the processing apparatus 100, except the noble gas, the treatment gas (the reducing gas or the nitrogen-containing gas) used in the activating treatment of a catalyst metal layer and the source gas (the carbon-containing gas) used in the growth of the graphene are introduced into the processing vessel 1 from the shower plate 59 positioned close to the wafer W, thereby increasing the reaction efficiency in the activating treatment or the graphene growth treatment. In this regard, the gap G1 from the lower surface of the transmission plate 39 of the processing vessel 1 to the upper surface of the stage 3, on which the wafer W is mounted, is preferably set to fall within a range of from 140 mm to 200 mm and more preferably within a range of from 160 mm to 185 mm with a view to, when performing a plasma treatment in the processing apparatus 100, sufficiently reducing the electron temperature of plasma near the wafer W to prevent damages to the graphene or a base film which grows on the surface of the wafer W. Furthermore, the gap G2 from the lower end of the shower plate 59 (the open positions of the gas discharge holes 65) to the upper surface of the stage 3, on which the wafer W is mounted, is preferably set equal to or larger than 80 mm and more preferably equal to or larger than 100 mm with a view to keeping, as high as possible, the reaction efficiency of the treatment gas used in the activating treatment of a catalyst metal layer or the source gas used in the growth of a graphene and with a view to, in case of the plasma treatment, suppressing the radiation of ions on the graphene or the base film which grows on the surface of the wafer W to reduce the damages to the graphene or the base film.

### <Exhaust Unit>

The exhaust unit 11 includes an exhaust room 17, an exhaust port 17a formed on the side surface of the exhaust room 17, an exhaust pipe 97 connected to the exhaust port 17a, and an exhaust device 99 connected to the exhaust pipe 97. While not shown in the drawings, the exhaust device 99 includes, e.g., a vacuum pump and a pressure control valve.

### <Plasma Generating Space and Mixing/Diffusing Space>

In case of performing a plasma treatment with the processing apparatus 100, a plasma-generating noble gas is introduced from the shower ring 57 into the space S1 of the processing vessel 1 between the transmission plate 39 which introduces microwaves and the shower plate 59. Accordingly, the space S1 serves as a plasma generating space mainly used to generate the plasma.

In case of performing a plasma treatment with the processing apparatus 100, the space S2 of the processing vessel 1 between the shower plate 59 and the stage 3 serves as a mixing/diffusing space within which the plasma generated in the space S1 is mixed with the treatment gas for the activating treatment or the carbon-containing gas as a source for the growth of the graphene, both of which are introduced by the shower plate 59, and within which the active species existing in the plasma are diffused toward the wafer W mounted on the stage 3.

### <Control Unit>

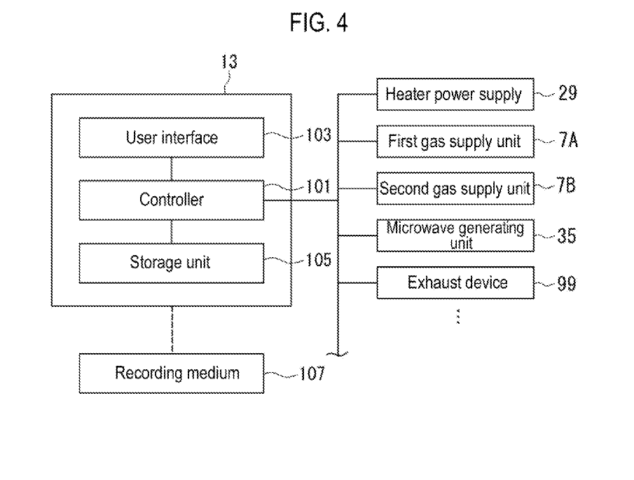

The control unit 13 is a module controller that controls the respective constituent parts of the processing apparatus 100. The control unit 13 is typically a computer. For example, as shown in FIG. 4, the control unit 13 includes a controller 101 provided with a CPU, a user interface 103 connected to the controller 101, and a storage unit 105. The controller 101 is a control means that controls the respective constituent parts of the processing apparatus 100 (e.g., the heater power supply 29, the first gas supply unit 7A, the second gas supply unit 7B, the microwave generating unit 35, the exhaust device 99, etc.) associated with the process conditions such as a temperature, a pressure, a gas flow rate, a microwave output and the like.

The user interface 103 includes a keyboard or a touch panel through which a process manager performs a command input operation or other operations to manage the processing apparatus 100, a display which visualizes and displays the operating situation of the processing apparatus 100, and so forth. The storage unit 105 stores recipes in which control programs (software) and process condition data for executing, under the control of the controller 101, various processes performed in the processing apparatus 100 are recorded. If necessary, in accordance with the instruction transmitted from the user interface 103, an arbitrary recipe is called out from the storage unit 105 and is executed by the controller 101, whereby a desired process is performed within the processing vessel 1 of the processing apparatus 100 under the control of the controller 101. The recipes such as control programs and process condition data may be stored in a computer-readable recording medium 107. As the recording medium 107, it may be possible to use, e.g., a CD-ROM, a hard disc, a flexible disc, a flash memory, or the like. Moreover, the recipes may be transmitted from other devices through, e.g., a dedicated line.

The processing apparatus 100 configured as above is capable of performing a treatment using low-electron-temperature microwave plasma mainly composed of radicals and is therefore suitable for an activating treatment of a catalyst metal layer as a pretreatment for the formation of the graphene. The processing apparatus 100 can be used as a plasma CVD apparatus that forms the graphene by a plasma CVD method, or a thermal CVD apparatus that performs formation of a graphene by a thermal CVD method. Accordingly, the processing apparatus 100 can sequentially implement, through a series of processes, an activating treatment of a catalyst metal layer and a graphene growth treatment using the plasma CVD method or the thermal CVD method, within the same processing vessel kept in a vacuum state. As mentioned above, if the processing apparatus 100 is used in the manufacture of the graphene, it is not necessary to replace a substrate (wafer W) between the activating treatment and the graphene growth treatment. This makes it possible to realize the improvement of a throughput, the simplification of facilities through consolidation, and the saving of energy.

### <Pretreatment and Graphene Formation>

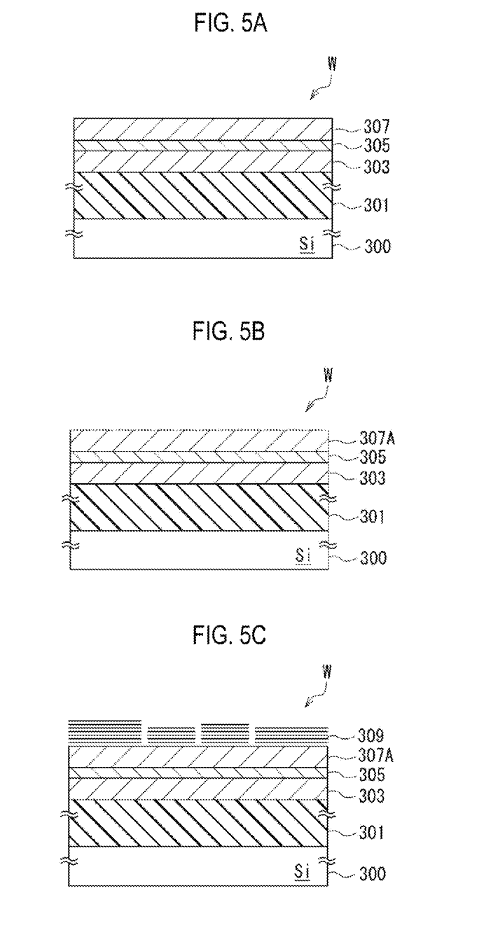

Next, the description will be made on a pretreatment method and a graphene forming method performed in the processing apparatus 100. FIGS. 5A, 5B and 5C are vertical sectional views of the surface of a wafer W and its vicinities explaining major steps of a graphene forming method. The graphene forming method according to the present embodiment includes an activating treatment performed prior to the graphene formation. The activating treatment is a step of treating and activating the surface of a catalyst metal layer with the plasma of a treatment gas including a reducing gas and nitrogen-containing gas. In the present embodiment, the activating treatment will be referred to as a “pretreatment (method)” of the graphene formation. In the below-mentioned graphene forming method including the pretreatment method, the conditions such as a gas flow rate, a microwave power and the like are set under the assumption that a wafer W of 200 mm in diameter is used as a workpiece. The conditions may be appropriately adjusted depending on the size of the workpiece.

First, a wafer W having a catalyst metal layer formed thereon is prepared. The gate valve G of the processing apparatus 100 is opened. The wafer W is carried into the processing vessel 1 and is mounted on the stage 3. As illustrated in FIG. 5A, the wafer W used herein may be of the type including an insulating layer 301 deposited on a surface layer of a silicon substrate 300, a first base layer 303 deposited on the insulating layer 301, a second base layer 305 deposited on the first base layer 303 and a catalyst metal layer 307 deposited on the second base layer 305.

The insulating layer 301 increases the adhesion between the catalyst metal layer 307 and the silicon substrate 300, thereby preventing the peeling of the catalyst metal layer 307. As the insulating layer 301, it may be possible to use, e.g., a SiO₂ film, a SiN film, an Al₂O₃ film, an MN film or the like. Considering the application to a multilayer wiring structure of a semiconductor device, the first base layer 303 and the second base layer 305 may be made of, e.g., an electrically conductive material such as Ti, TiN, Ta, TaN, Zr, ZrB₂ or the like. As the method of forming the first base layer 303 and the second base layer 305, it may be possible to use a well-known deposition technology such as a sputtering method, a vapor deposition method, a CVD method, a plating method or the like. It is preferred that the thickness of the first base layer 303 and the second base layer 305 is within a range of, e.g., from 5 nm to 100 nm. The insulating layer 301, the first base layer 303 and the second base layer 305 are optional and may not be formed.

The catalyst metal layer 307 is a metal film that serves as a catalyst for accelerating the growth of the graphene. As the metal that constitutes the catalyst metal layer 307, it may be possible to cite, e.g., metals such as Ni, Co, Cu, Ru, Pt, Pd and the like, or alloys containing these metals. Among these kinds of metals, it is preferable to select Ni or Co in case of forming the graphene of the multilayer structure. As the method of forming the catalyst metal layer 307, it may be possible to use a well-known deposition technology such as a sputtering method, a vapor deposition method, a CVD method, a plating method or the like. The thickness of the catalyst metal layer 307 is preferably, e.g., within a range of from 10 nm to 200 nm and more preferably within a range of from 20 nm to 50 nm. If the thickness of the catalyst metal layer 307 is less than 10 nm, the metal agglomerates in an island shape, and a carbon nanotube grows from the agglomerated metal. This may possibly hinder the growth of the graphene. Even if the catalyst metal layer 307 is formed thick to have a thickness of more than 200 nm, it is not possible to enhance the effect of accelerating the growth of the graphene.

As the workpiece substrate, it may be possible to use, e.g., a quartz substrate, a sapphire substrate or the like in place of the wafer W which is a semiconductor substrate. In case of a low-temperature treatment, it may be possible to use a glass substrate, a plastic (polymer) substrate or the like.

In the pretreatment, for example, the exhaust device 99 is operated to depressurize and evacuate the interior of the processing vessel 1. During that time, a plasma-generating noble gas (e.g., an Ar gas) is introduced from the shower ring 57 into the processing vessel 1, and the reducing gas (e.g., a H₂ gas) and the nitrogen-containing gas (e.g., a N₂ gas) are respectively introduced from the shower plate 59 into the processing vessel 1. In this state, the microwaves generated in the microwave generating unit 35 are guided in a specified mode to the planar antenna 33 through the waveguide tube 47 and the coaxial waveguide tube 49 and are introduced into the processing vessel 1 through the microwave radiating holes 33a of the planar antenna 33 and the transmission plate 39. The plasma-generating noble gas is first converted to plasma by the microwaves. At a plasma-ignited timing, the reducing gas and the nitrogen-containing gas are further converted to plasma. Using the plasma generated in this manner, the surface of the catalyst metal layer 307 existing on the wafer W is activated to convert the catalyst metal layer 307 to an activated catalyst metal layer 307A as illustrated in FIG. 5B. In FIG. 5B, the surface of the activated catalyst metal layer 307A is indicated by a broken line. In the activating treatment, an oxide existing on the surface of the catalyst metal layer 307 is reduced and activated using the plasma of a mixture gas containing a reducing gas and a nitrogen-containing gas. Since the nitrogen-containing gas is used in the activating treatment, it is possible to stabilize the crystalline structure of the catalyst metal layer 307 and to form a preferred orientation surface. This makes it possible to form the graphene into the multilayer structure in the next graphene forming step.

With a view to efficiently activating the catalyst metal layer 307, the activating treatment temperature is set such that the temperature of the wafer W falls preferably within a range of from 300 degrees C. to 600 degrees C., more preferably within a range of from 300 degrees C. to 500 degrees C. and most preferably within a range of from 300 degrees C. to 400 degrees C. If the activating treatment temperature is less than 300 degrees C., the oxide existing on the surface of the catalyst metal layer 307 is not sufficiently reduced, which leads to insufficient activation. If the activating treatment temperature is more than 600 degrees C., there is a fear that the activated catalyst metal layer 307A may agglomerate.

In order to efficiently generate an increased amount of radicals in the plasma, the internal pressure of the processing vessel 1 is set preferably within a range of from 66.7 Pa to 400 Pa (from 0.5 Torr to 3 Torr) and more preferably within a range of from 66.7 Pa to 133 Pa (from 0.5 Torr to 1 Torr).

In order to efficiently generate active species in the plasma, the flow rate of the reducing gas (e.g., a H₂ gas) is set preferably within a range of from 100 mL/min (sccm) to 2000 mL/min (sccm) and more preferably within a range of from 100 mL/min (sccm) to 500 mL/min (sccm).

In order to efficiently generate active species in the plasma, the flow rate of the nitrogen-containing gas (e.g., a N₂ gas) is set preferably within a range of from 100 mL/min (sccm) to 2000 mL/min (sccm) and more preferably within a range of from 100 mL/min (sccm) to 1000 mL/min (sccm).

In order to stably generate the plasma, the flow rate of the plasma-generating noble gas (e.g., an Ar gas) is set preferably within a range of from 100 mL/min (sccm) to 2000 mL/min (sccm) and more preferably within a range of from 300 mL/min (sccm) to 1000 mL/min (sccm).

In the activating treatment, in order to reliably activate the catalyst metal layer 307 and to form a preferred orientation surface by stabilizing the crystalline structure of the activated catalyst metal layer, the ratio of the reducing gas (e.g., a H₂ gas) to the nitrogen-containing gas (e.g., a N₂ gas) (namely, the reducing gas: the nitrogen-containing gas) is set preferably within a range of from 10:1 to 1:10 and more preferably within a range of from 5:1 to 1:5.

In order to efficiently generate active species in the plasma and enabling the generation of a graphene at a low temperature, the microwave power is set preferably within a range of from 250 W to 4000 W and more preferably within a range of from 300 W to 1000 W.

In order to reliably activate the catalyst metal layer 307 while preventing the agglomeration thereof, the treatment time is set preferably within a range of from 30 seconds to 15 minutes and more preferably within a range of from 3 minutes to 10 minutes.

When finishing the activating treatment, the supply of the microwaves is first stopped and then the supply of the reducing gas and the nitrogen-containing gas is stopped.

### <Graphene Formation>

Subsequently, the graphene formation is performed. In order to prevent the activated catalyst metal layer 307A activated by the activating treatment from being deactivated, the graphene formation is preferably performed subsequently to the activating treatment and more preferably performed in succession to the activating treatment within the same processing vessel. In the processing apparatus 100, the graphene formation can be performed by, e.g., a plasma CVD method, a thermal CVD method or the like. The following description will discuss a case where the graphene formation treatment is performed by a plasma CVD method and a case where the graphene formation treatment is performed by a thermal CVD method.

### <Plasma CVD Method>

After the activating treatment, a noble gas (e.g., an Ar gas) is supplied at a predetermined flow rate. In this state, the microwaves are guided from the microwave generating unit 35 to the planar antenna 33 through the waveguide tube 47 and the coaxial waveguide tube 49 and are introduced into the processing vessel 1 through the transmission plate 39. By virtue of the microwaves, the plasma-generating noble gas is first converted to plasma. At a plasma-ignited timing, a carbon-containing gas (e.g., a C₂H₄ gas) and, if necessary, a H₂ gas are introduced into the processing vessel 1 through the shower plate 59. Thus, the carbon-containing gas (and the H₂ gas) is converted to plasma. Then, as shown in FIG. 5C, a graphene 309 is formed on the activated catalyst metal layer 307A by virtue of the microwave plasma thus generated.

In order to implement a low-temperature process, the temperature of the growth treatment of the graphene 309 by the plasma CVD method is set such that the temperature of the wafer W falls preferably within a range of from 300 degrees C. to 600 degrees C., more preferably within a range of from 300 degrees C. to 500 degrees C. and most preferably within a range of from 300 degrees C. to 400 degrees C. In the present embodiment, the activating treatment is performed as a pretreatment. Thus, the graphene 309 can grow even at a low temperature of preferably 500 degrees C. or less and more preferably 400 degrees C. or less. The temperature of the plasma CVD treatment may differ from or may be equal to the temperature of the activating treatment. It is preferred that the temperature of the plasma CVD treatment is equal to the temperature of the activating treatment. In this case, it is possible to increase the throughput.

In order to generate an increased amount of radicals in the plasma, the internal pressure of the processing vessel 1 is set preferably within a range of from 66.7 Pa to 667 Pa (from 0.5 Torr to 5 Torr) and more preferably within a range of from 266 Pa to 400 Pa (from 2 Torr to 3 Torr).

In order to efficiently generate active species in the plasma, the flow rate of the carbon-containing gas (e.g., a C₂H₄ gas) is set preferably within a range of from 5 mL/min (sccm) to 200 mL/min (sccm) and more preferably within a range of from 6 mL/min (sccm) to 30 mL/min (sccm).

In order to stably generate the plasma, the flow rate of the plasma-generating noble gas (e.g., an Ar gas) is set preferably within a range of from 100 mL/min (sccm) to 2000 mL/min (sccm) and more preferably within a range of from 300 mL/min (sccm) to 1000 mL/min (sccm).

If a H₂ gas is introduced into the processing vessel 1 together with the carbon-containing gas (e.g., a C₂H₄ gas), it is possible to increase the growth speed of the graphene 309 and to improve the quality of the graphene 309. However, the use of the H₂ gas is optional. In case of using the H₂ gas, in order to efficiently generate active species in the plasma, the flow rate of the H₂ gas is set preferably within a range of from 100 mL/min (sccm) to 2000 mL/min (sccm) and more preferably within a range of from 300 mL/min (sccm) to 1200 mL/min (sccm).

In order to efficiently generate active species and accelerating the growth of the graphene 309, the microwave power is set preferably within a range of from 250 W to 4000 W and more preferably within a range of from 250 W to 1000 W.

To grow the graphene 309 up to a high enough layer number while preventing reduction of a catalyst activity, the treatment time is set preferably within a range of from 30 seconds to 60 minutes and more preferably within a range of from 1 minute to 30 minutes.

When forming the graphene 309 by the plasma CVD method, the carbon-containing gas is not limited to the ethylene (C₂H₄) gas. It may be possible to use, e.g., other hydrocarbon gases such as methane (CH₄), ethane (C₂H₆), propane (C₃H₈), propylene (C₃H₆), acetylene (C₂H₂) and the like, and other carbon-containing gases such as methanol (CH₃OH), ethanol (C₂H₅OH) and the like. As the plasma-generating noble gas, it may be possible to use not only the Ar gas but also, e.g., He, Ne, Kr, Xe and the like.

In the plasma CVD method, the graphene 309 can be deposited in a layered shape on the activated catalyst metal layer 307A. In the plasma CVD method, the graphene 309 can be formed even at a low temperature of 600 degrees C. or less, preferably 500 degrees C. or less and more preferably 400 degrees C. or less. It is therefore possible to form the graphene 309 even on a substrate having a low heat resistance, such as a glass substrate, a synthetic resin (polymer) substrate or the like.

### <Thermal CVD Method>

After the activating treatment, the noble gas (e.g., an Ar gas not used for the purpose of generating plasma in the thermal CVD treatment) is supplied. In this state, a carbon-containing gas (e.g., a C₂H₄ gas) and a H₂ gas (if necessary) are further introduced into the processing vessel 1 through the shower plate 59. The carbon-containing gas is thermally decomposed in the space S2 to form the graphene 309 on the activated catalyst metal layer 307A as shown in FIG. 5C.

In order to implement a low-temperature process, the temperature of the growth treatment of the graphene 309 by the thermal CVD method is set such that the temperature of the wafer W falls preferably within a range of from 300 degrees C. to 600 degrees C., more preferably within a range of from 300 degrees C. to 500 degrees C. and most preferably within a range of from 400 degrees C. to 500 degrees C. In the present embodiment, the activating treatment is performed as a pretreatment. Thus, the graphene 309 can grow by performing the thermal CVD method even at a low temperature of 500 degrees C. or less. The temperature of the thermal CVD treatment may differ from or may be equal to the temperature of the activating treatment. It is preferred that the temperature of the thermal CVD treatment is equal to the temperature of the activating treatment. In this case, it is possible to increase the throughput.

In order to keep the growth speed of the graphene sufficiently high, the internal pressure of the processing vessel 1 is set preferably within a range of from 66.7 Pa to 667 Pa (from 0.5 Torr to 5 Torr) and more preferably within a range of from 400 Pa to 667 Pa (from 3 Torr to 5 Torr).

In order to efficiently grow the graphene 309, the flow rate of the carbon-containing gas (e.g., a C₂H₄ gas) is set preferably within a range of from 5 mL/min (sccm) to 200 mL/min (sccm) and more preferably within a range of from 6 mL/min (sccm) to 30 mL/min (sccm).

When forming the graphene 309 by the thermal CVD method, a noble gas and a H₂ gas are introduced into the processing vessel 1 together with the carbon-containing gas. This makes it possible to increase the growth speed of the graphene 309 and to improve the quality of the graphene 309. However, the use of the noble gas and the H₂ gas is optional. In case of introducing the noble gas, in order to efficiently grow the graphene 309, the flow rate of the noble gas is set preferably within a range of from 100 mL/min (sccm) to 2000 mL/min (sccm) and more preferably within a range of from 300 mL/min (sccm) to 1000 mL/min (sccm). In case of introducing the H₂ gas, in order to efficiently grow the graphene 309, the flow rate of the H₂ gas is set preferably within a range of from 100 mL/min (sccm) to 2000 mL/min (sccm) and more preferably within a range of from 300 mL/min (sccm) to 1000 mL/min (sccm).

In order to grow the graphene 309 up to a high enough layer number while preventing reduction of a catalyst activity, the treatment time is set preferably within a range of from 30 seconds to 120 minutes and more preferably within a range of from 30 minutes to 90 minutes.

When forming the graphene 309 by the thermal CVD method, the carbon-containing gas is not limited to the ethylene (C₂H₄) gas. It may be possible to use, e.g., other hydrocarbon gases such as methane (CH₄), ethane (C₂H₆), propane (C₃H₈), propylene (C₃H₆), acetylene (C₂H₂) and the like, and other carbon-containing gases such as methanol (CH₃OH), ethanol (C₂H₅OH) and the like. As the noble gas, it may be possible to use not only the Ar gas but also other noble gases, e.g., He, Ne, Kr, Xe and the like.

In the thermal CVD method, the graphene 309 can be deposited in a layered shape on the activated catalyst metal layer 307A. In the present embodiment, the graphene 309 can be formed even at a temperature of 500 degrees C. or less which is quite lower than the temperature used in the conventional thermal CVD method. Moreover, in the thermal CVD method, the graphene 309 does not suffer from any damage that may be caused by electrons or ions. Thus, it is possible to prevent the generation of crystal detects or the introduction of impurities, thereby forming the graphene 309 which is low in impurity content, high in G/D ratio and good in crystallinity.

In the aforementioned manner, the graphene 309 is formed by the plasma CVD method or the thermal CVD method. Thereafter, the supply of microwaves (in case of the plasma CVD method) and the supply of gases are stopped and the internal pressure of the processing vessel 1 is adjusted. Then, the gate valve G is opened and the wafer W is carried out. The graphene forming method of the present embodiment may include an optional step other than the activating treatment step and the graphene forming step.

### <N₂ Purge Treatment Step>

A step of purging the interior of the processing vessel 1 (a N₂ purge treatment step) may be provided between the activating treatment step and the graphene forming step. The N₂ purge treatment can be implemented by rapidly evacuating the interior of the processing vessel 1 with the exhaust device 99 in a state in which the wafer W having the activated catalyst metal layer 307A is mounted on the stage 3 and then supplying the N₂ gas. The internal atmosphere of the processing vessel 1 can be replaced by performing the N₂ purge treatment. Due to the N₂ purge treatment, it is possible to obtain an effect of suppressing agglomeration of the activated catalyst metal layer 307A, preventing growth of a carbon nanotube and accelerating normal growth of the graphene. The agglomeration suppressing effect provided by the N₂ purge treatment becomes particularly effective in case where the activated catalyst metal layer 307A contains Co.

It is preferred that the temperature of the N₂ purge treatment is equal to the temperature of the activating treatment.

In order to sufficiently replace the gas used in the activating treatment step to prevent the gas from affecting the graphene growth, the internal pressure of the processing vessel 1 in the N₂ purge treatment is set preferably within a range of from 66.7 Pa to 667 Pa (from 0.5 Torr to 5 Torr) and more preferably within a range of from 133 Pa to 400 Pa (from 1 Torr to 3 Torr).

In order to sufficiently replace the gas used in the activating treatment step, the flow rate of the N₂ gas in the N₂ purge treatment is set preferably within a range of from 100 mL/min (sccm) to 2000 mL/min (sccm) and more preferably within a range of from 200 mL/min (sccm) to 1000 mL/min (sccm). In the N₂ purge treatment, a noble gas, e.g., an Ar gas or the like, may be introduced into the processing vessel 1 together with the N₂ gas.

In order to maintain the activated state while suppressing agglomeration of the activated catalyst metal layer 307A, the treatment time is set preferably within a range of from 30 seconds to 10 minutes and more preferably within a range of from 1 minute to 5 minutes.

As described above, according to the graphene forming method of the present embodiment, it is possible to manufacture the graphene 309 which is formed in a high density on the surface of the activated catalyst metal layer 307A existing on the wafer W and which has a multilayer structure. The graphene 309 thus formed has a high utility value, e.g., in the application of a via-wiring line of a semiconductor device or in the application of a channel material of a transistor.

Next, the present invention will be described in more detail with reference to examples. However, the present invention is not limited by these examples.

### Example 1

### Formation of a Graphene by a Plasma CVD Method

As shown in FIG. 5A, a wafer W was prepared by depositing an insulating layer, base layers (two base layers) and a catalyst metal layer on a silicon substrate. Describing with reference to FIG. 5A, a SiO₂ film of about 500 nm in thickness formed using TEOS (tetraethoxysilane) was used as an insulating layer 301. A first base layer 303 was formed by Ti to have a thickness of 10 nm. A second base layer 305 was formed by TiN to have a thickness of 5 nm. A catalyst metal layer 307 was formed by Ni or Co to have a thickness of 30 nm. The wafer W was carried into a processing vessel of a processing apparatus having the same configuration as the processing apparatus 100 shown in FIG. 1. After the surface of the catalyst metal layer is activated under the following conditions, a graphene grows by performing a plasma CVD method. An N₂ purge treatment was performed under the following conditions between the activating treatment and the plasma CVD treatment.

### <Conditions of Activating Treatment>

Treatment pressure: 133 Pa (1 Torr)

### Treatment Gases:

H₂ gas 462 mL/min (sccm)

N₂ gas 100 mL/min (sccm)

Ar gas 450 mL/min (sccm)

Microwave power: 0.5 kW
Treatment Temperature: 470 degrees C. (in terms of the substrate temperature)
Treatment Time: 5 minutes

### <Conditions of Purge Treatment>

Treatment pressure: 400 Pa (3 Torr)

### Treatment Gases:

N₂ gas 200 mL/min (sccm)

Ar gas 450 mL/min (sccm)

Treatment Temperature: 470 degrees C. (in terms of the substrate temperature)

Treatment Time: 2 minutes

### <Conditions of Plasma CVD (Graphene Growth)>

Treatment pressure: 400 Pa (3 Torr)

Treatment gases:

C₂H₄ gas 6.3 mL/min (sccm)

H₂ gas 370 mL/min (sccm)

Ar gas 450 mL/min (sccm)

Microwave power: 0.5 kW
Treatment Temperature: 470 degrees C. (in terms of the substrate temperature)
Treatment Time: 30 minutes

### Examples 2 and 3 and Comparative Examples 1 to 3

The graphene grew by performing an activating treatment, a N₂ purge treatment and a plasma CVD treatment in the same manner as in example 1 except that the conditions of the activating treatment of the catalyst metal layer used in example 1 are changed to ones shown in

Table 1. Also shown in Table 1 are the conditions of the activating treatment of example .

| | | | Treatment Gas | | | | Treatment | |
|---|---|---|---|---|---|---|---|---|
| | Microwave | Pressure | [mL/min (sccm)] | | | | Time | Temperature |
| | Power [kW] | [Pa] | Ar | H₂ | N₂ | NH₃ | [min] | [° C.] |
| Example 1 | 0.5 | 133 | 450 | 462 | 100 | — | 5 | 470 |
| Example 2 | 0.5 | 133 | 450 | 462 | — | 185 | 5 | 470 |
| Example 3 | 0.5 | 133 | 450 | — | 100 | 185 | 5 | 470 |
| Comparative | 0.5 | 133 | 450 | 462 | — | — | 5 | 470 |
| Example 1 | | | | | | | | |
| Comparative | 0.5 | 133 | 450 | — | 100 | — | 5 | 470 |
| Example 2 | | | | | | | | |
| Comparative | 0.5 | 133 | 450 | — | — | 185 | 5 | 470 |
| Example 3 | | | | | | | | |

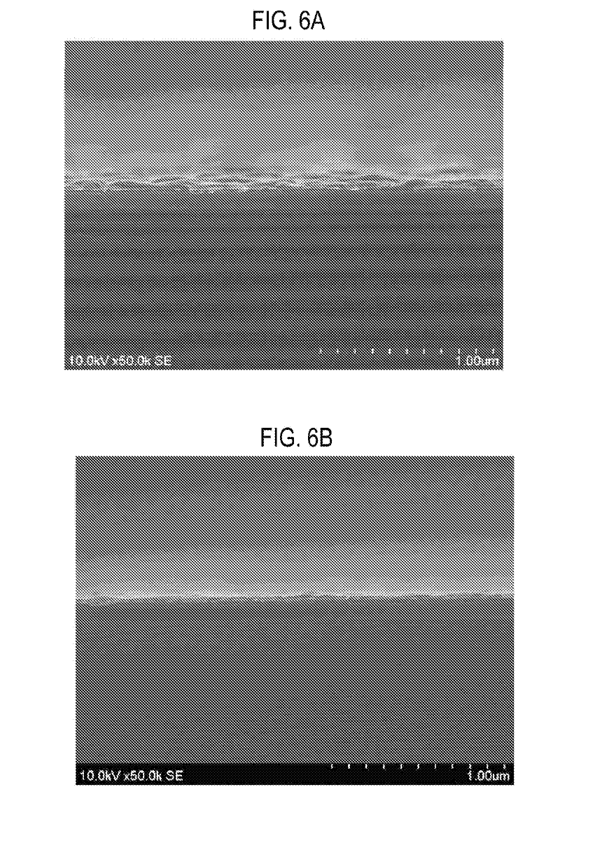

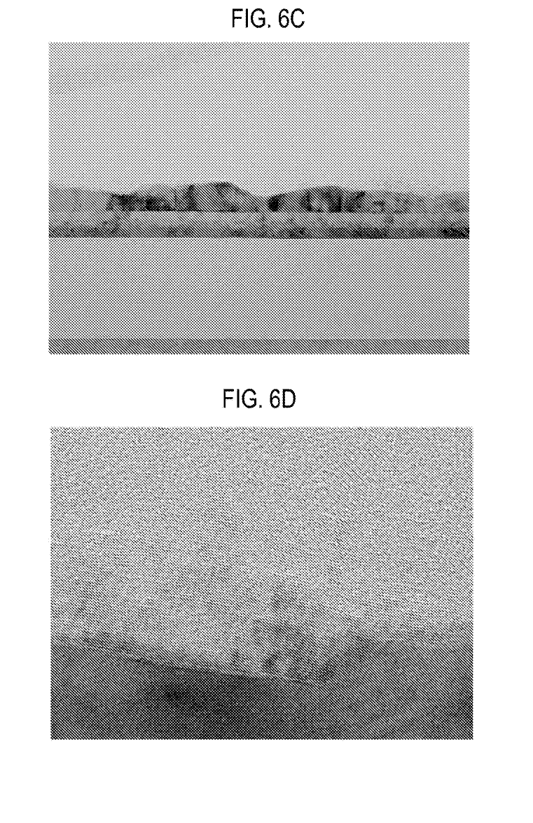

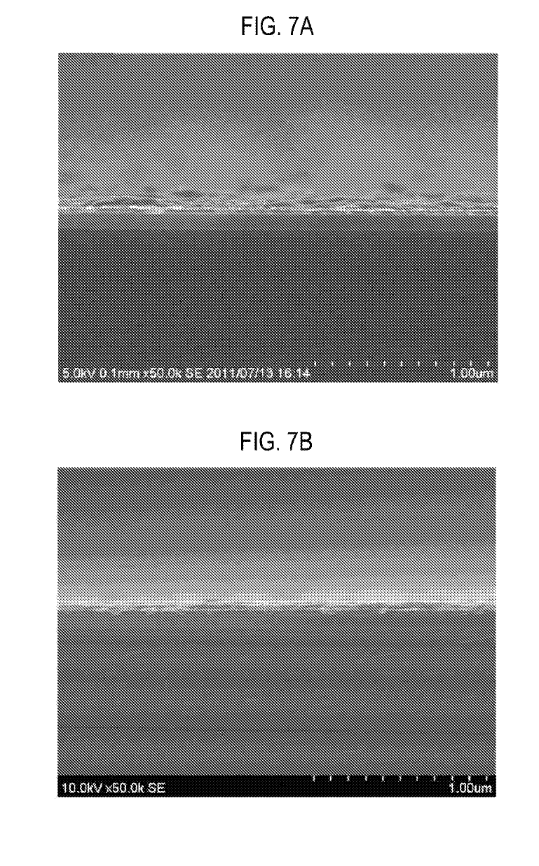

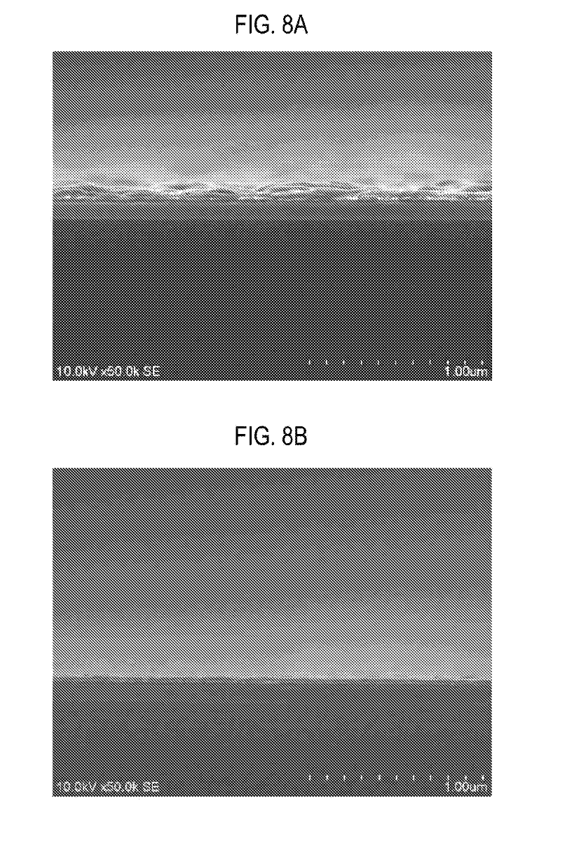

The cross-sectional structure of the graphene grown in this manner was observed with a scanning electron microscope (SEM). As a result, the growth of a graphene sheet having a multilayer structure was confirmed in examples 1 to 3. The result of use of Ni as the material of the catalyst metal layer in example 1 is shown in FIG. 6A and the result of use of Co as the material of the catalyst metal layer in example 1 is shown in FIG. 6B. The cross-sectional structure of the graphene formed by using Ni as the material of the catalyst metal layer in example 1 was observed by a transmission electron microscope (TEM), the result of which is shown in FIG. 6C. The partially-enlarged image thereof is shown in FIG. 6D. Furthermore, the result of use of Ni as the material of the catalyst metal layer in example 2 is shown in FIG. 7A and the result of use of Co as the material of the catalyst metal layer in example 2 is shown in FIG. 7B. In addition, the result of use of Ni as the material of the catalyst metal layer in example 3 is shown in FIG. 8A and the result of use of Co as the material of the catalyst metal layer in example 3 is shown in FIG. 8B. In comparative examples 1 to 3, the growth of a carbon nanotube and the growth of carbon were observed and the growth of a graphene sheet having a multilayer structure was hindered (The results are not shown).

### Example 4

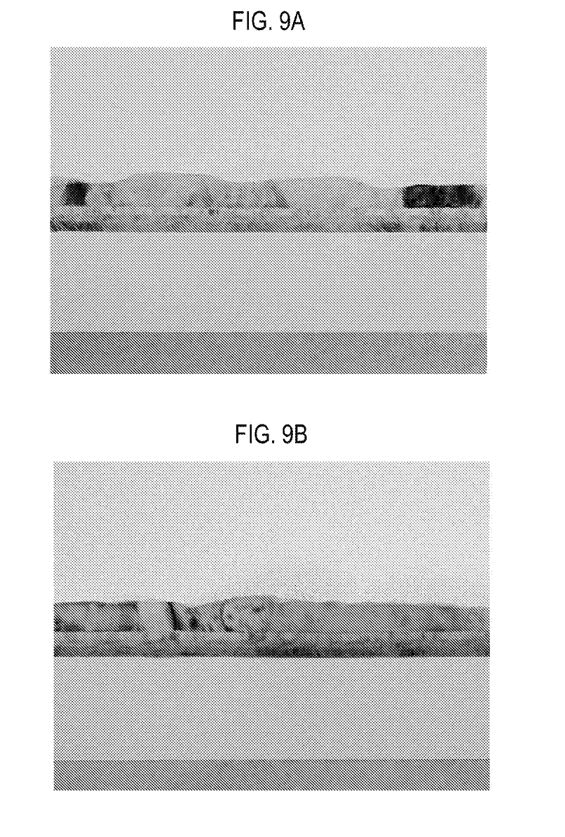

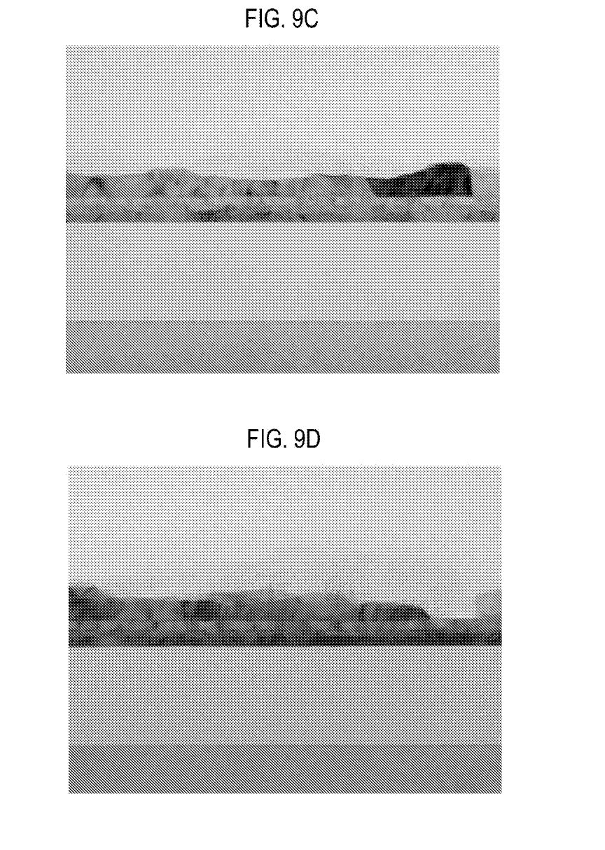

A graphene grew by performing an activating treatment, a N₂ purge treatment and a plasma CVD treatment in the same manner as in example 1 except that the time of plasma CVD (graphene growth) in example 1 is changed to 1 minute, 3 minutes, 5 minutes or 15 minutes. Ni was used as the material of the catalyst metal layer. The cross-sectional structures of the graphenes grown for the respective times were observed by a transmission electron microscope (TEM). The result of the graphene growth for 1 minute is shown in FIG. 9A. The result of the graphene growth for 3 minute is shown in FIG. 9B. The result of the graphene growth for 5 minute is shown in FIG. 9C. The result of the graphene growth for 15 minute is shown in FIG. 9D. It was confirmed in FIGS. 9A to 9D that a graphene sheet having a multilayer structure can be sufficiently formed even if the time of plasma CVD (graphene growth) is from 1 minute to 15 minutes.

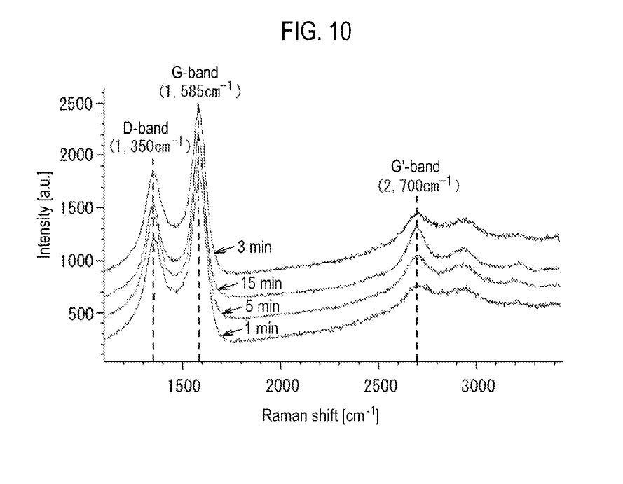

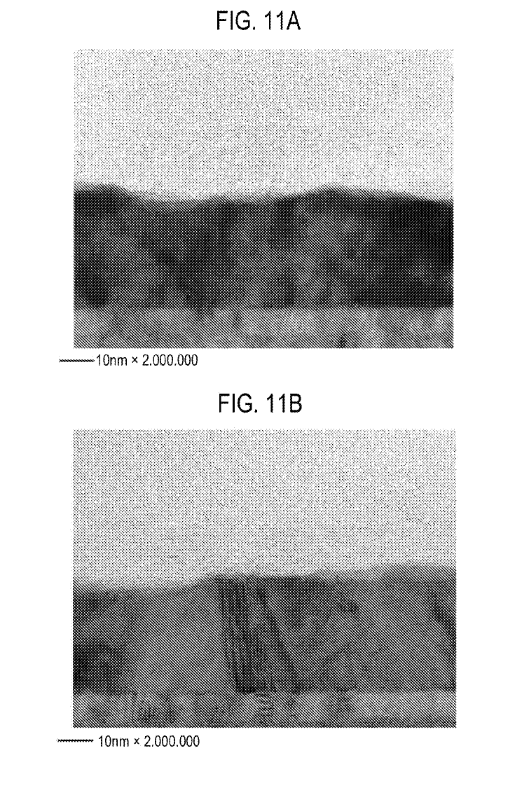

The crystallinity of the graphenes obtained by performing the plasma CVD (graphene growth) treatments for the respective times in example 4 was measured by a Raman scattering spectroscopy. FIG. 10 shows a Raman shift chart. It was confirmed in FIG. 10 that, in either of the plasma CVD (graphene growth) treatments performed for 1 minute, 3 minutes, 5 minutes or 15 minutes, the ratio (G/D ratio) of the peak of a G band appearing near 1585 cm⁻¹ to the peak of a D band appearing near 1350 cm⁻¹ is approximately 1.4 and the graphenes having high crystallinity are formed. In FIG. 10, the number of graphene layers formed on the catalyst metal layer is as high as 10 layers or more. For that reason, it is believed that the peak of a G′ band (2700 cm⁻¹) indicating the interaction between the graphene layers becomes smaller.

### Example 5

A graphene grew by performing an activating treatment, a N₂ purge treatment and a plasma CVD treatment in the same manner as in example 1 except that the treatment temperatures [namely, the temperatures of the activating treatment, the N₂ purge treatment and the plasma CVD (graphene growth) treatment] in example 1 are changed to 350 degrees C. or 390 degrees C. Ni was used as the material of the catalyst metal layer. The cross-sectional structures of the graphenes grown after performing the activating treatment of the catalyst metal layer at the respective temperatures were observed by a transmission electron microscope (TEM). The result obtained at the treatment temperature of 350 degrees C. is shown in FIG. 11A and the result obtained at the treatment temperature of 390 degrees C. is shown in FIG. 11B. It was confirmed in FIGS. 11A and 11B that a graphene sheet having a multilayer structure can be sufficiently formed even if the treatment temperature is 350 degrees C. In addition, the domain size of the graphene tends to become smaller as the treatment temperature decreases.

### Example 6

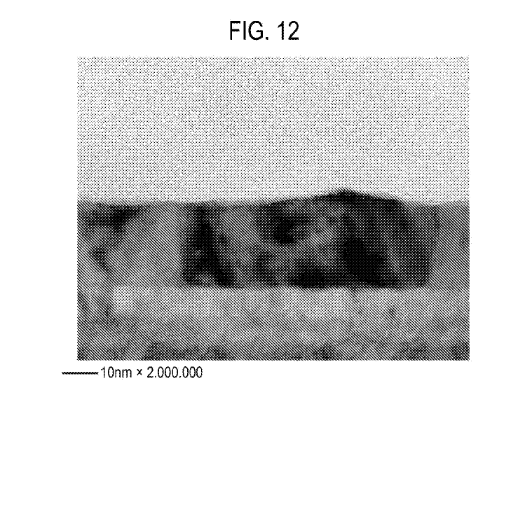

A graphene grew by performing an activating treatment, a N₂ purge treatment and a plasma CVD treatment in the same manner as in example 2 except that the time of plasma CVD (graphene growth) in example 2 is changed to 1 minute. Ni was used as the material of the catalyst metal layer. The cross-sectional structure of the graphene thus grown was observed by a transmission electron microscope (TEM). The result is shown in FIG. 12. It was confirmed in FIG. 12 that a graphene sheet having a multilayer structure can be formed even if the combination of a H₂ gas and a NH₃ gas is used as the treatment gas for the activating treatment.

### Example 7

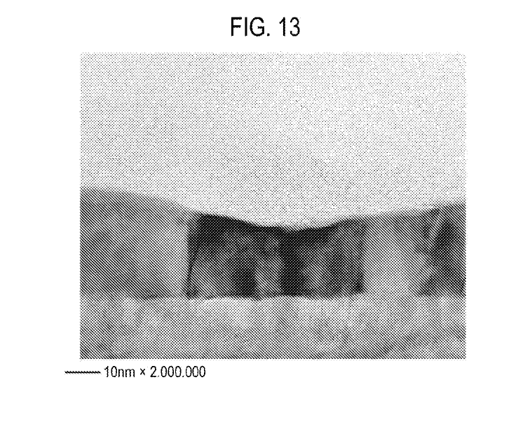

A graphene grew by performing an activating treatment, a N₂ purge treatment and a plasma CVD treatment in the same manner as in example 3 except that the time of plasma CVD (graphene growth) in example 3 is changed to 1 minute. Ni was used as the material of the catalyst metal layer. The cross-sectional structure of the graphene thus grown was observed by a transmission electron microscope (TEM). The result is shown in FIG. 13. It was confirmed in FIG. 13 that a graphene sheet having a multilayer structure can be formed even if the combination of a N₂ gas and a NH₃ gas is used as the treatment gas for the activating treatment.

### Example 8

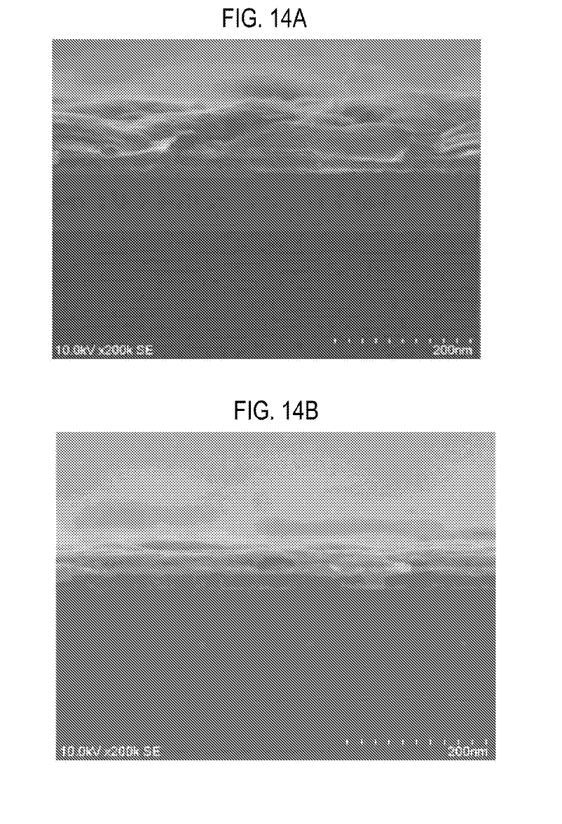

A graphene grew by performing an activating treatment and a plasma CVD treatment in the same manner as in example 1 except that a N₂ purge treatment is not performed. Ni or Co was used as the material of the catalyst metal layer. The cross-sectional structure of the graphene thus grown was observed by a scanning electron microscope (SEM). As a result, the growth of a graphene sheet having a multilayer structure was confirmed. The result of use of Ni as the material of the catalyst metal layer in example 8 is shown in FIG. 14A and the result of use of Co as the material of the catalyst metal layer in example 8 is shown in FIG. 14B. It was confirmed in FIGS. 14A and 14B that a graphene sheet having a multilayer structure can grow even if the N₂ purge treatment is not performed. However, it was confirmed that, if Co is used as the material of the catalyst metal layer, a carbon nanotube is slightly formed. In view of the aforementioned result, it is considered that, in case where the activated catalyst metal layer is formed by a metal susceptible to agglomeration such as Co or the like, the N₂ purge treatment provides an effect of suppressing the growth of a carbon nanotube and accelerating the growth of a graphene.

### Example 9

A graphene grew by performing an activating treatment and a N₂ purge treatment in the same manner as in example 1 except that, instead of the plasma CVD treatment used in example 1, a thermal CVD treatment is performed under the below-mentioned conditions. Ni or Co was used as the material of the catalyst metal layer.

### <Conditions of Thermal CVD (Graphene Growth)>

Treatment pressure: 400 Pa (3 Torr)

### Treatment Gases:

C₂H₄ gas 30 mL/min (sccm)

H₂ gas 200 mL/min (sccm)

Ar gas 450 mL/min (sccm)

Treatment Temperature: 470 degrees C. (in terms of the substrate temperature)
Treatment Time: 60 minutes

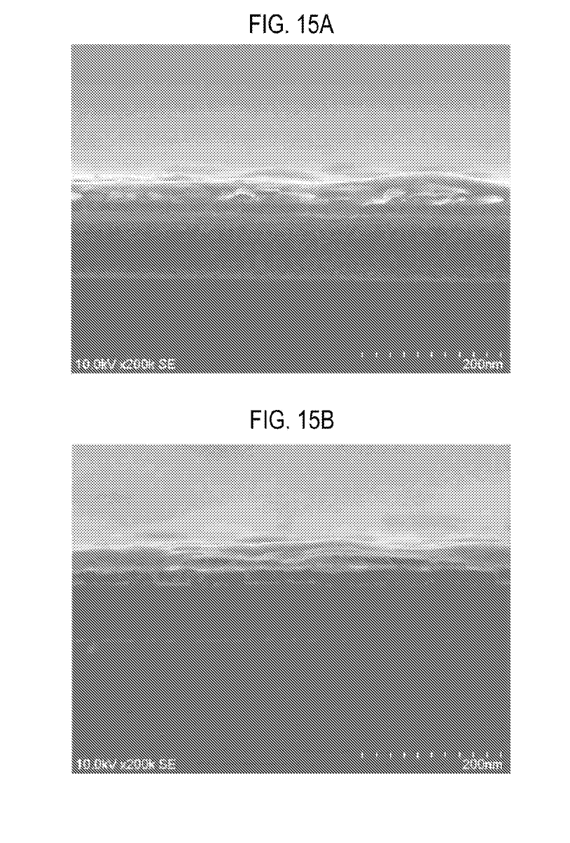

The cross-sectional structure of the graphene grown in this manner was observed with a scanning electron microscope (SEM). The result of use of Ni as the material of the catalyst metal layer in example 9 is shown in FIG. 15A and the result of use of Co as the material of the catalyst metal layer in example 9 is shown in FIG. 15B. According to the results of cross section observation by the SEM shown in FIGS. 15A and 15B and the spectrum of a G′ (2D) band obtained by a Raman scattering spectroscopy, it was confirmed that a graphene sheet having a multilayer structure can be sufficiently formed by a thermal CVD method at a substrate temperature of 470 degrees C. According to the Raman scattering spectroscopy, it was confirmed that, in case of the thermal CVD method, the G/D ratio is increased about 1.5 times as high as the G/D ratio of the plasma CVD method (The result is not shown).

From the aforementioned test results, it was confirmed that by performing an activating treatment by the plasma of a treatment gas containing a reducing gas and a nitrogen-containing gas in the processing apparatus 100 capable of generating microwave plasma, a graphene of multilayer structure showing high crystallinity can be formed by either of the plasma CVD method and the thermal CVD method. Accordingly, it was confirmed that the pretreatment method and the graphene forming method of the present embodiment can efficiently form a graphene of multilayer structure showing high crystallinity on the surface of a substrate as a workpiece by including the step of activating the surface of the catalyst metal layer with the plasma of a treatment gas containing a reducing gas and a nitrogen-containing gas.

As described above, according to the pretreatment method of the present embodiment, the activation ratio of a catalyst can be increased by including the step of activating the catalyst metal layer with the plasma of a treatment gas containing a reducing gas and a nitrogen-containing gas. According to the graphene forming method of the present embodiment which includes the pretreatment method, a graphene having a multilayer structure and showing good crystallinity can be formed on the surface of a workpiece at a low temperature of 600 degrees C. or less and preferably 500 degrees C. or less.

While one embodiment of the present invention has been described in detail by way of example, the present invention is not limited to the aforementioned embodiment but may be modified in many different forms. For example, although an example in which the activating treatment is performed by the plasma processing apparatus of RLSA microwave plasma type has been described in the aforementioned embodiment, it may be possible to use other types of microwave plasma methods. Instead of the microwave plasma, it may be possible to use other kinds of plasma such as inductively-coupled plasma, capacitively-coupled plasma and the like.

In the aforementioned embodiment, there has been described a configuration in which, using the processing apparatus 100, the pretreatment and the CVD treatment (the plasma CVD treatment or the thermal CVD treatment) for the growth of a graphene are performed one after another within the single processing vessel 1. However, the pretreatment and the CVD treatment may be performed within different processing vessels. In this case, use of, e.g., a multi-chamber type processing system, makes it possible to sequentially implement the pretreatment and the CVD treatment while maintaining a vacuum state.

The subject international application claims the priority of Japanese Patent Application No. 2011-245747 filed on Nov. 9, 2011, the entire content of which is incorporated herein by reference.

What is claimed is:

1. A pretreatment method which is performed before a graphene grows by performing a CVD method on a catalyst metal layer formed on a workpiece, the method comprising:
a plasma treatment process in which the catalyst metal layer is activated by applying plasma of a treatment gas including a reducing gas and a nitrogen-containing gas on the catalyst metal layer.

2. The method of claim 1, wherein a volume ratio of the reducing gas to the nitrogen-containing gas is within a range of from 10:1 to 1:10.

3. The method of claim 1, wherein the reducing gas is a hydrogen gas, and the nitrogen-containing gas is a nitrogen gas or an ammonia gas.

4. The method of claim 1, wherein the reducing gas is a hydrogen gas or an ammonia gas, and the nitrogen-containing gas is a nitrogen gas.

5. The method of claim 1, wherein the catalyst metal layer is made of one or more kinds of metals selected from the group consisting of Ni, Co, Cu, Ru, Pd and Pt.

6. A graphene forming method for growing a graphene on a catalyst metal layer formed on a workpiece, the method comprising:
a plasma treatment process in which the catalyst metal layer is activated by applying plasma of a treatment gas including a reducing gas and a nitrogen-containing gas on the catalyst metal layer; and
a process of growing the graphene by a CVD method on the catalyst metal layer subjected to the plasma treatment.

7. The method of claim 6, wherein the process of growing the graphene is performed by a plasma CVD method.

8. The method of claim 7, wherein a treatment temperature of by the plasma CVD method is within a range of from 300 degrees C. to 600 degrees C.

9. The method of claim 7, wherein source gas plasma is generated by introducing microwaves into a processing vessel through a planar antenna having a plurality of microwave radiating holes, and the graphene is formed by the source gas plasma.

10. The method of claim 9, wherein the planar antenna is a radial line slot antenna.

11. The method of claim 6, wherein the process of growing the graphene is performed by a thermal CVD method.

12. The method of claim 11, wherein a treatment temperature of the thermal CVD method is within a range of from 300 degrees C. to 600 degrees C.

13. The method of claim 6, wherein a volume ratio of the reducing gas to the nitrogen-containing gas is within a range of from 10:1 to 1:10.

14. The method of claim 6, wherein the reducing gas is a hydrogen gas, and the nitrogen-containing gas is a nitrogen gas or an ammonia gas.

15. The method of claim 6, wherein the reducing gas is a hydrogen gas or an ammonia gas, and the nitrogen-containing gas is a nitrogen gas.

16. The method of claim 6, wherein the catalyst metal layer is made of one or more kinds of metals selected from the group consisting of Ni, Co, Cu, Ru, Pd and Pt.

17. A graphene fabrication apparatus, comprising:
a processing vessel configured to process a workpiece and provided with an upper opening portion;
a mounting stand arranged within the processing vessel and configured to mount the workpiece thereon;
a dielectric plate configured to close the opening portion of the processing vessel;
a planar antenna installed outside the dielectric plate and configured to introduce microwaves into the processing vessel, the planar antenna including a plurality of microwave radiating holes;
a gas introduction unit configured to introduce a treatment gas into the processing vessel, the gas introduction unit including a plurality of gas discharge holes formed to face the workpiece mounted on the mounting stand; and
an exhaust port connected to an exhaust device which depressurizes and evacuates the interior of the processing vessel,
wherein the gas introduction unit is connected to a gas supply source configured to supply a treatment gas including a reducing gas and a nitrogen-containing gas used in a pretreatment performed prior to a growth of a graphene on a catalyst metal layer formed on the workpiece and a source gas supply source configured to supply a source gas of the graphene used in a process to grow the graphene by a CVD method on the catalyst metal layer subjected to the pretreatment.

18. The apparatus of claim 17, which is configured such that the pretreatment and the process of growing the graphene are performed one after another within the same processing vessel.

19. The apparatus of claim 17, wherein the gas introduction unit includes a plurality of gas discharge holes formed to face a surface of the workpiece mounted on the mounting stand.
